(19) United States
(12) Patent Application Publication
(10) Pub. No.: US 2015/0255654 A1
(43) Pub. Date: Sep. 10, 2015

(54) SOLAR POWER CELL MATRIX

(71) Applicant: Morgan Solar Inc., Toronto (CA)

(72) Inventors: John Paul MORGAN, Toronto (CA); Anton FISCHER, Toronto (CA); Stefan MYRSKOG, Maple (CA); Nicholas COISH, Toronto (CA); Brett BARNES, Toronto (CA); Michael SINCLAIR, Toronto (CA); Timothy KWAN, Toronto (CA)

(73) Assignee: Morgan Solar Inc., Toronto (CA)

(21) Appl. No.: 14/196,523

(22) Filed: Mar. 4, 2014

(51) Int. Cl. H01L 31/05

(52) U.S. Cl. CPC H01L 31/05

(57) ABSTRACT

A solar cell array including a matrix of solar cells arranged on a substrate in rows and columns; and a plurality of conductor elements connecting the solar cells within each column in parallel and the solar cells of each row in series. The conductor elements are arranged on the substrate in an optical path of light to the solar cells. The conductor elements are physically dimensioned to reduce interference with the optical path and have current-carrying capacity configured to conduct current within a predetermined range of anticipated operating currents.

### FIELD

The present disclosure relates to solar energy systems that use concentrated or non-concentrated photovoltaic cells.

### BACKGROUND

Solar energy systems typically use one or more solar modules for the purpose of capturing solar energy and converting the solar energy to electrical energy. Solar modules, which may also be referred to as solar panels, typically include a plurality of photovoltaic (PV) cells, more generally referred to as solar cells. These solar cells may be electrically connected to each other in series or in parallel, in a solar cell array.

Because of the interconnected nature of the solar cells in the array, the performance of the solar module as a whole may be adversely impacted by variations in the solar cells (e.g., due to manufacturing inconsistencies) or optical misalignment (e.g., misalignment between light concentrators and solar cells). Such variations can give rise to imbalances in current among the solar cells in the solar cell array. Differences in the amount of solar energy received by individual solar cells in the solar module (e.g., due to the solar module being partially shaded) may also create imbalances in current among the solar cells. Such imbalances may adversely impact the performance of the solar module and may damage the solar module.

### BRIEF DESCRIPTION OF THE DRAWINGS

Reference will now be made, by way of example, to the accompanying drawings which show example embodiments of the present application, and in which:

FIG. 1 shows an isometric view of an example solar module in accordance with the present disclosure;

FIG. 2 shows an exploded view of the example solar module of FIG. 1;

FIG. 3 shows an example solar cell array in accordance with the present disclosure;

FIG. 4 shows an example solar cell unit in accordance with the present disclosure;

FIG. 5 shows an electrical diagram of an example solar cell array in accordance with the present disclosure; and

FIGS. 6A and 6B show electrical diagrams of example prior art solar cell arrays.

Similar reference numerals may have been used in different figures to denote similar components.

### DESCRIPTION OF EXAMPLE EMBODIMENTS

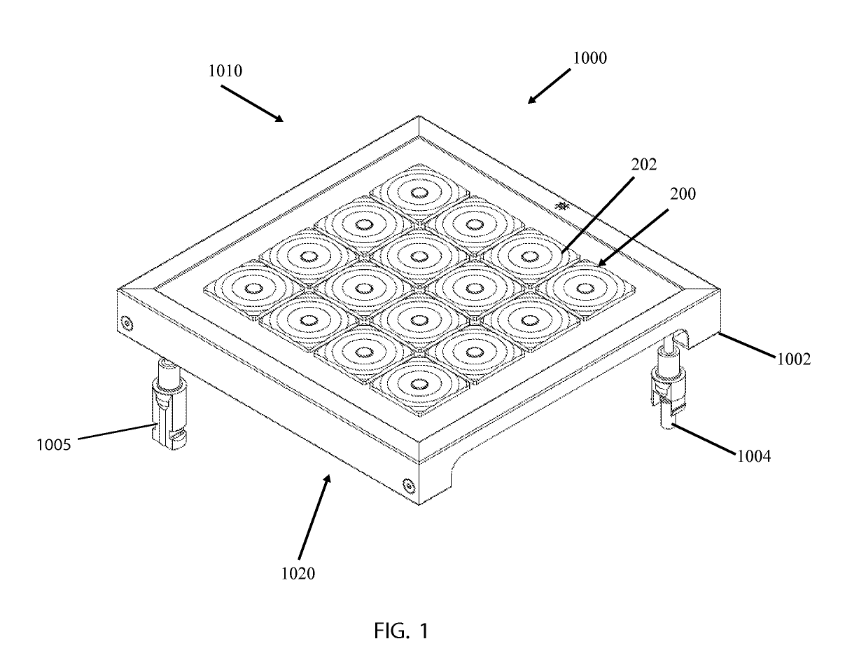

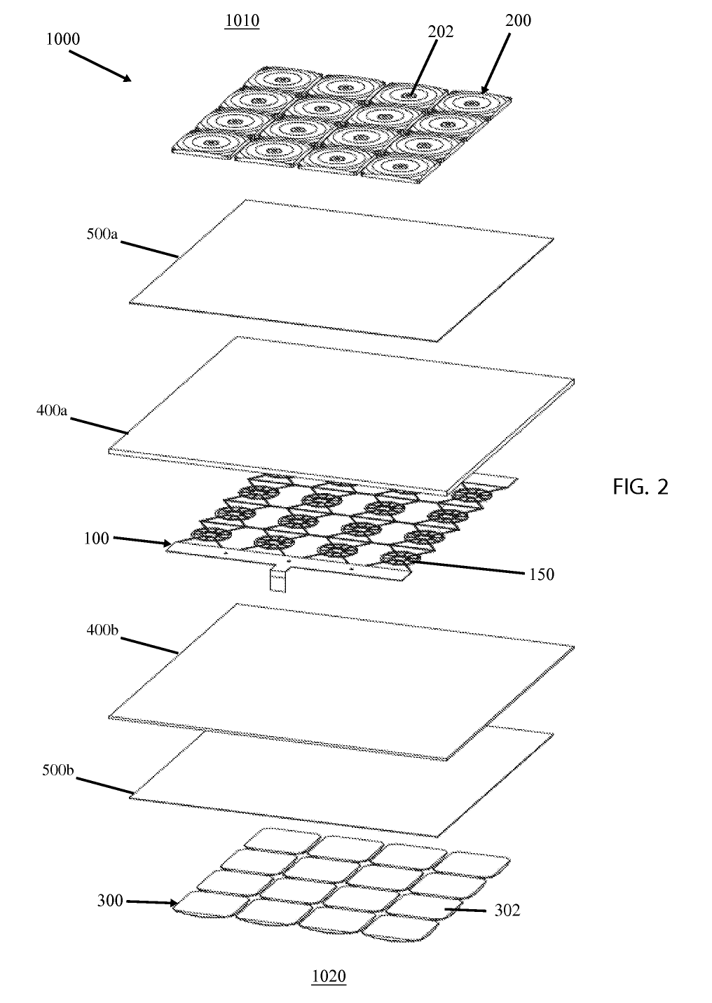

Reference is first made to FIGS. 1 and 2, showing an example solar module 1000 in accordance with the present disclosure. The solar module 1000, which may also be referred to as a solar panel, may include a solar cell array 100 sandwiched between a focusing layer 200 and a back reflector layer 300. The focusing layer 200 is typically positioned on a light-receiving side 1010, also referred to as a top or front side, of the solar module 1000, and may serve to concentrate and direct light to the solar cells of the solar cell array 100. The back reflector layer 300 is typically positioned on an opposing side 1020 to the light-receiving side 1010, also referred to as a bottom or back side, of the solar module 1000, and may serve to reflect light that passed through the solar cell array 100 back towards the solar cell array 100.

The solar module 1000 may include one or more other layers, such as one or more support layers 400a, 400b (collectively support layers 400, also referred to as substrate layers) that may serve to support and/or protect the layers of the solar module 1000. In the example shown, support layers 400 may be optically transparent layers (e.g., glass sheets) sandwiching the solar cell array 100. The solar module 1000 may further include one or more compliant layers 500a, 500b (collectively compliant layers 500) which may be elastically deformable and may serve to mitigate any difference in thermal expansion between the other layers of the solar module 1000. For example, while the support layer(s) 400 and the solar cell array 100 may be expected to have little thermal expansion/contraction, the focusing layer 200 and the back reflector layer 300 may be expected to have non-negligible thermal expansion/contraction. In the example shown, the compliant layer(s) 500 may be positioned between the support layers 400a, 400b and each of the focusing layer 200 and the back reflector layer 300. The compliant layer(s) 500 may not deform or otherwise affect the dimensions of the other layers in the solar module 1000, but may instead expand or be compressed to complement any expansion/contraction of the other layers. The compliant layer(s) 500 may be formed from any suitable compliant and/or elastomeric material (e.g., silicone, ethylene-vinyl acetate (EVA) or an ionomer), and may be selected to have sufficient elongation (e.g., about 500% elongation) to mitigate expected differences in thermal expansion/contraction between the other layers of the solar module 1000.

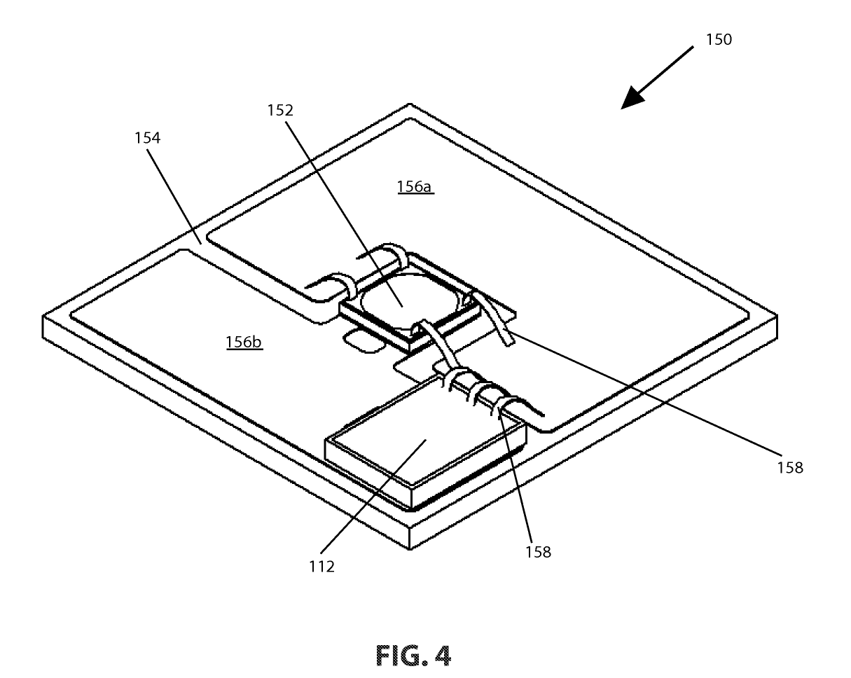

The focusing layer 200 may be supported by and optically coupled to a substrate, such as the support layer 400a. The focusing layer 200 may include a plurality of light concentrating structures 202, which may each include one or more lenses. Each of the light concentrating structures 202 may be configured to focus light on at least one corresponding reflector element 302 of the reflector layer 300. Each reflector element 302 may be configured to redirect the focused light onto at least one corresponding solar cell 152 (see FIG. 4) of the solar cell array 100. For example, each light concentrating structure 202 may be optically coupled with (e.g., aligned to focus light onto) a respective one reflector element 302, and each reflector element 302 may be optically coupled with (e.g., aligned to reflect light onto) a respective one solar cell 152. A light concentrating structure 202 and a corresponding reflector element 302 may therefore operate in conjunction to focus light onto a corresponding solar cell 152 of the solar cell array 100.

In various examples, different types of light concentrating optics may be used to focus light onto the solar cells 152 of the solar cell array 100, with or without reflection by a reflector layer 300. For example, the focusing layer 200 may include suitable types of concentrating optics that may cooperate with the reflector layer 300 to direct light onto the solar cells 152 of the solar cell array 100, such as described above; or the focusing layer 200 may include suitable concentrating optics to focus light directly onto the solar cells 152, without cooperating with a reflector layer 300. The concentrating optics may be any suitable optical element that is configured to collect and concentrate light. For example, the light concentrating optics may include lenses, mirrors and/or lightguides, among others. Examples of concentrating optics are described in U.S. Pat. No. 7,873,257 entitled “Light-Guide Solar Panel and Method of Fabrication Thereof”, U.S. Patent Application Publication No. 2012/0019942 entitled “Light-Guide Solar Panel and Method of Fabrication Thereof”, U.S. Patent Application Publication No. 2013/0233384 entitled “Planar Solar Energy Concentrator”, U.S. Patent Application Publication No. 2013/0247960 entitled “Solar-Light Concentration Apparatus”, and U.S. Patent Application Publication No. 2013/0104984 entitled “Monolithic Photovoltaic Solar Concentrator”, all of which are incorporated by reference in their entireties.

The solar module 1000 may further include a frame 1002 (not shown in FIG. 2) holding the layers of the solar module 1000 together. A positive connector 1004 and a negative connector 1005 (not shown in FIG. 2) may extend from the frame 1002, for connecting the solar module 1000 to a power supply. The solar module 1000 may further be mounted on a solar tracking system, such as the systems described in U.S. Patent Application Publication No. 2013/0319508 entitled “Self-Ballasted Apparatus for Solar Tracking” and U.S. Patent Application Publication No. 2013/0056614 entitled “Multi-Dimensional Maximum Power Point Tracking”, the entireties of which are all hereby incorporated by reference.

The frame 1002 may hold the layers of the solar module 1000 together in such a way that there is little or no space between adjacent layers. Such an arrangement may help to reduce or prevent optical misalignment (e.g., between the light concentrating structures 202, the reflector elements 302, and their respective solar cells 152), which may occur from expansion or contraction of the layers when there is space between the layers.

In an example operation, light received at the light-receiving side 1010 may be concentrated by the focusing layer 200. The concentrated light may then pass through the transparent layers (e.g., the support layer(s) 400 and compliant layer(s) 500) and may be reflected by the back reflector layer 300 back towards the solar cell array 100. The concentrated light may be received by the solar cell array 100 to be converted to electrical energy by one or more solar cells 152 of the solar cell array 100.

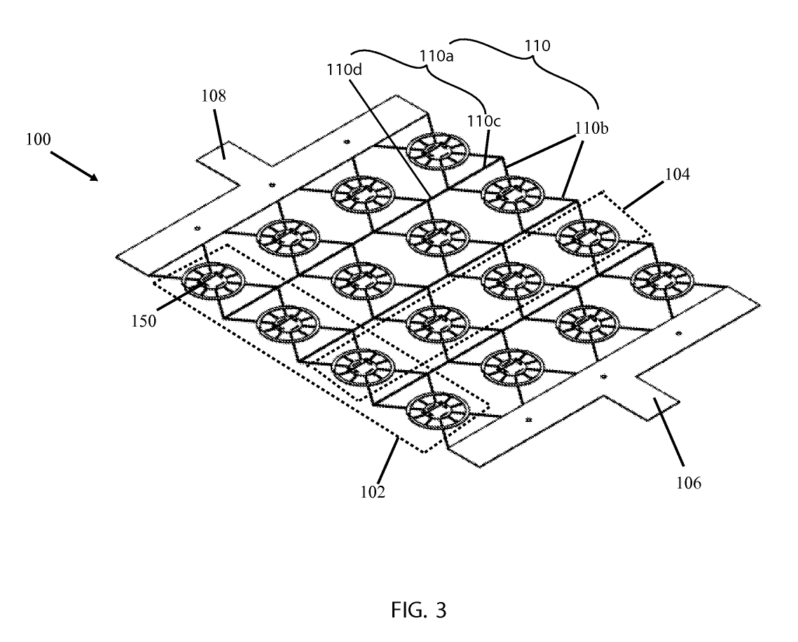

FIG. 3 shows the solar cell array 100 in greater detail. The solar cell array 100 may include a plurality of solar cell units 150 arranged in rows 102 (also referred to as strings) and columns 104 (also referred to as nodes), in an interconnected matrix. As shown in greater detail in FIG. 4, each solar cell unit 150 may include a single solar cell 152 and may provide electrical connections to the solar cell 152. The solar cell unit 150 may include or be supported on a structure designed to disperse heat, to help avoid overheating the solar cell 152. In the example shown, the solar cell unit 150 may be supported by a structure having radiating arms, to help disperse heat.

The solar cell array 100 may provide a power supply connection 106 and a ground connection 108, for connecting to a power supply and a ground source (not shown), respectively. Any suitable power supply and ground source may be used. The power supply may include one or more batteries. In some examples, the power supply may itself be charged by electrical energy converted by the solar cell array 100.

In the example shown in FIG. 3, the solar cell array 100 includes a 4-by-4 arrangement of solar cell units 150. Other arrangements, which may have more or less rows and columns, may be possible. The solar cell units 150 may be spaced apart, for example at a spacing of about 40 mm center-to-center along each row 102 and each column 104. In some examples, the spacing between solar cell units 150 along a row 102 may differ from the spacing along a column 104. Other physical dimensions may be suitable.

The solar cells 152 may be electrically connected in an interconnected matrix by a plurality of conductor elements 110 (e.g., electrical traces or elongate members) connecting the solar cell units 150. The conductor elements 110 may be provided on a substrate (e.g., the support layer 400b) supporting the solar cell units 150. The conductor elements 110 may be made from any suitable conductive material, such as copper or silver. In some examples, the conductor elements 110, the power supply connection 106 and the ground connection 108 may be integrally formed, such as being cut out from a single sheet of conductive material (e.g., a thin copper sheet). Where the solar cell units 150 are supported by a heat dispersing structure, the heat dispersing structure may also be cut out from the same sheet of conductive material. In some examples, at least some of the conductor elements 110 may be formed separately and be connected to the solar cell array 100 by crimping or soldering, for example.

The conductor elements 110 may serve to connect the solar cells 152 within each column 104 in parallel, and the solar cells 152 within each row 102 in series. The solar cells 152 in each column 104 may be electrically connected in series by at least one conductor element 110 to a respective one of the solar cells 152 in an adjacent column 104.

The conductor elements 110 may be arranged to avoid or minimize interference in the optical path of light as it travels through the layers of the solar module 1000. The solar cell units 150 typically occupy a relatively small area of the solar cell array 100 and are typically spaced apart from each other, with the conductor elements 110 bridging the space between the solar cell units 150. Accordingly, it may be useful for the conductor elements 110 to be designed so as to reduce or minimize their interference with the optical path of light passing through the solar cell array 100. For example, the conductor elements 110 may be physically dimensioned to be relatively narrow (e.g., having a minimum cross-sectional area of about 0.1 mm in thickness and about 0.1 mm in width), so as to reduce their interference with the optical path.

There is typically a trade-off between thinness and current-carrying capacity, also referred to as ampacity, of the conductor elements 110. Typically, thicker conductor elements 110 provide greater ampacity. Conductor elements 110 that are too thin may not be able to support anticipated operating currents and may overheat, which may damage the solar module 1000. The conductor elements 110 thus may be physically dimensioned to reduce interference with the optical path while maintaining sufficient ampacity for conducting current within a predetermined range of anticipated operating currents. The predetermined range of anticipated operating currents may be determined by engineering design and testing, for example. The anticipated operating currents may be a function of whether the current is flowing in a series connection along a row 102 or whether it is flowing in a parallel connection along a column 104, and may also be a function of where the current is flowing in the solar cell array 100. The anticipated operating currents may take into consideration variations in current flow under different normal operating conditions, as discussed further below. For example, anticipated operating currents may be about 200 mA or less for certain conductor elements 110, while other conductor elements 110 may have greater anticipated operating currents (e.g., up to 10 A in certain conditions).

In some examples, as discussed below, the conductor elements 110 may not be uniform in shape and/or size. The physical dimensions of some of the conductor elements 110 may be reduced because the anticipated operating currents flowing through them is expected to be relatively low, because the anticipated operating currents flowing through them is expected to be of limited time duration and/or because of less restrictive design constraints, while the physical dimensions of others of the conductor elements 110 may be greater because the anticipated operating currents flowing through them is expected to be relatively higher, because the anticipated operating currents flowing through them is expected to be over a sustained time duration and/or because design constraints are more restrictive.

In some examples, parallel electrical connection of the solar cells 152 within a column 104 may be provided by a first set of elongate conductor elements 110a (also referred to as parallel conductor elements 110a) that extend between adjacent columns 104. A second set of conductor elements 110b (also referred to as series conductor elements 110b) may provide series electrical connection between the solar cells 152 in a row 102. The first set of conductor elements 110a may be in electrical connection with the second set of conductor elements 110b, forming an interconnected matrix or grid.

The series conductor elements 110b may be sized to reduce operating losses. Under normal operating conditions, the current flowing in series connections may be no more than 1 A, for example about 200 mA or less. This current in a single series connection may be divided over two or more series conductor elements 110b if the series connection is provided by two or more series conductor elements 110b in parallel. In an example where a series connection between two solar cells 152 is provided by two series conductor elements 110b in parallel, it may be expected that each series conductor element 110b carries no more than 0.2-0.18 A/2 (i.e., no more than 0.1-0.09 A each) under anticipated normal operating conditions. As a result the series conductor elements 110b may be sized as small as 0.1 mm in thickness and width.

The parallel conductor elements 110a may be expected to carry varying current loads, depending on the operating condition. For example, when all solar cells 152 are fully performing (e.g., the solar module 1000 is unshaded), there may be little or no current flowing along a column 104. However, if one or more solar cells 152 is poorly performing or not functional (e.g., the solar module 1000 is partially shaded), current may flow along parallel connections to bypass the poorly performing or not functional solar cells(s) 152 and this current may be relatively high. It should be noted that fully unshaded, fully shaded and partially shaded conditions are all considered within normal operating conditions. For example, the parallel conductor elements 110a may be designed to carry up to 7.5-10 A in normal operating conditions, and the parallel conductor elements 110a may be sized accordingly. The amount of current that may be expected to flow in the parallel conductor elements 110a under normal operating conditions may be dependent on the arrangement of bypass diodes in the solar cell array 100, as discussed further below.

Typically, under normal operating conditions, it may be expected that current would flow along parallel connections only for a small portion of the total operating time (e.g., for less than an hour total over a total operating time of 24 hours). Accordingly, while the series conductor elements 110b may be designed to minimize efficiency loss and heat generation, it may be acceptable for the parallel conductor elements 110b to be designed for a greater amount of efficiency loss and heat generation. For example, significant loss of efficiency (e.g., more than 5%) and significant heat generation (e.g., an increase of more than 10° C.) may be acceptable for current flow along parallel conductor elements 110a, while such loss of efficiency and heat generation may not be acceptable for current flow along series conductor elements 110b. Accordingly, the design constraints for the series conductor elements 110b may be more restrictive than those for the parallel conductor elements 110a.

In some examples, the design constraints for the parallel conductor elements 110a may be mainly to ensure that heat generation during normal operating conditions do not result in thermal damage to the solar module 1000 (e.g., temperatures do not reach 90° C. or higher). Thus, the parallel conductor elements 110a may be sized to be relatively thin, for example they may have the same or smaller cross-sectional area as the series conductor elements 110b. The size limitations for the parallel conductor elements 110a may be determined based on thermal simulations and/or calculations, for example.

In some examples, the solar cell array 100 may be designed to enable the parallel conductor elements 110a to dissipate any generated heat at regular intervals. For example, the parallel conductor elements 110a may extend no more than about 2 cm between heat dissipating structures, so that any generated heat may be dissipated by the heat dissipating structures (e.g., radiating arms) supporting the solar cell units 150 at regular intervals.

In the example embodiment of FIG. 3, the parallel conductor elements 110a may be divided into two sets of parallel conductor sections: a first set of conductor sections 110c, and a second set of conductor sections 110d. The first set of conductor sections 110c may create a parallel connection between two or more series conductor elements 110b to the same cell solar cell unit 150. The second set of conductor sections 110d may create a parallel connection between two adjacent solar cell units 150 within a column 104. Parallel conductor sections 110c and 110d may have different ampacity requirements, and therefore they need not be of the same thickness. The difference in ampacity requirements between the conductor sections 110c and 110d may occur in part because of a multiplicity of current paths that take place between the ends of the parallel conductor sections 110c. This multiplicity of current paths may reduce the ampacity requirements for parallel conductor sections 110c relative to those of conductor sections 110d which do not have parallel current paths between their two end points. Therefore, the thickness and width of the conductor sections 110c may be reduced to arrive at a smaller cross section than conductor elements 110d, which may help to further reduce the interference of the conductor sections 110c in the optical path.

Depending on the method of fabrication of the solar cell array 100, it may not be practical to have conductor sections 110c and 110d be of different thicknesses. For example, if the solar cell array 100 is fabricated from a single sheet of copper, it may be practical to fabricate parallel conductor sections 110c and 110d with differing thicknesses; however this may not be practical if the conductor sections 110c, 110d of the parallel conductor elements 110a are made of a continuous wire that is electrically connected to the rows 102 (e.g., using some physical method such as soldering or crimping). In the case where the conductor sections 110c, 110d have the same thickness or cross-sectional area, the minimum thickness or cross-sectional area may be determined by the minimum thickness or cross-sectional area that is sufficient to satisfy the ampacity requirements of the conductor sections 110d. In the example embodiment of FIG. 3, the conductor sections 110c and 110d may have the same cross-sectional area, and therefore the required thickness or cross-sectional area of the conductor element 110a may be determined to be that of the conductor sections 110d.

In some example embodiments, the first set of conductor elements 110a may have less ampacity than the ampacity of the second set of conductor elements 110b. For example, where both sets of conductor elements 110a, 110b are formed from the same conductive material (e.g., cut from the same sheet, such as a copper sheet), the first set of conductor elements 110a may have a minimum conductive cross-sectional area that is less than a minimum conductive cross-sectional area of the second set of conductor elements 110b. Such an arrangement may be suitable if a multiplicity of bypass diodes (described further below) are used in a column 104, since current flowing in a parallel connection may be expected to be lower than current flowing in a series connection, under normal operating conditions. The conductor elements 110b providing series connections may be designed to have sufficient ampacity to avoid fusing or damage to the components (e.g., silicone components) of the solar module 1000 in the event of a cell shunt. In the context of the present disclosure, normal operating conditions may include conditions that include temperature fluctuations, changes in wind loads and fully shaded, partially shaded and fully unshaded conditions. Damage to any component or portion of the solar module 1000 may not be part of normal operating conditions.

In some example embodiments, the first set of conductor elements 110a may have a greater ampacity than the second set of conductor elements 110b. For example, where both sets of conductor elements 110a, 110b are formed from the same conductive material, the first set of conductor elements 110a may have a minimum conductive cross-sectional area that is greater than a minimum conductive cross-sectional area of the second set of conductor elements 110b.

In some examples, there may be more than one conductor element 110 electrically connecting two adjacent solar cells 152 in series or in parallel. In such an arrangement, an effective minimum conductive cross-sectional area may be calculated as the total of the minimum conductive cross-sectional areas of each of the conductor elements 110 connecting the two adjacent solar cells 152 in parallel or in series. Thus, where both sets of conductor elements 110a, 110b are formed from the same conductive material (e.g., cut from the same sheet, such as a copper sheet), the first set of conductor elements 110a may have an effective minimum conductive cross-sectional area that is less than an effective minimum conductive cross-sectional area of the second set of conductor elements 110b. For example, by designing the solar cell array 100 such that the number of conductor elements 110b connecting two adjacent solar cells 152 in a row 102 is greater than the number of conductor elements 110a connecting two adjacent solar cells 152 in a column 104, the minimum conductive cross-sectional areas of individual conductor elements 110a, 110b in both sets of conductor elements 110a, 110b may be substantially equal while still achieving a greater effective minimum conductive cross-sectional area for the second set of conductor elements 110b.

Such a design, which reduces the number of parallel conductor elements 110a, may help to reduce the interference of the conductor elements 110 in the optical path while ensuring that the conductor elements 110 provide sufficient ampacity for expected operating currents. A smaller effective minimum conductive cross-sectional area, which results in lower ampacity for the first set of conductor elements 110a compared to the second set of conductor elements 110b, may be acceptable since it may be expected that, in the majority of time under normal operating conditions, less current would be expected flow along a column 104 compared to along a row 102.

In some examples, the physical dimensions (e.g., width, thickness or diameter) of at least a subset of the conductor elements 110 (e.g., the parallel conductor elements 110a) may be selected such that heat generated by the subset of conductor elements 110 is substantially negligible (e.g., less than 5° C.) when an expected average operating current (e.g., about 200 mA or less) flows therethrough; and the heat generated by the subset of conductor elements 110 is elevated but does not cause the focusing layer 200 or reflector layer 300 to exceed a predetermined heat threshold (e.g., as determined according to material properties, such as the properties of silicone and/or polymeric material used in the solar module 1000, or according to a standard; for example, the heat threshold may be about 90° C. or lower) when an operating current at the upper limit of the predetermined range of anticipated operating currents (e.g., up to about 10 A) flows therethrough in the hottest expected ambient operating conditions, and the heat generated by the subset of conductor elements 110 is elevated but does not cause the focusing layer 200 or the reflector layer 300 to exceed a second predetermined heat threshold (e.g., as determined according to material properties, such as the properties of silicone and/or polymeric material used in the solar module 1000, or according to a standard; for example, the heat threshold may be about 70° C. or lower) when an expected average current at the upper limit of the predetermined range of anticipated operating currents flows therethrough in the hottest expected ambient operating conditions.

The predetermined heat threshold may be selected to be lower than the heat profile at which the solar cell array 100 or the solar cell module 1000 would suffer physical damage. The predetermined heat threshold may be determined based on specifications and/or testing of the solar cell array 100 or the solar cell module 1000. The physical dimensions of the conductor elements 110 or a subset of the conductor elements 110 may be determined using calculations, testing and/or thermal simulations under different normal operating conditions (e.g., fully unshaded, fully shaded and partially shaded conditions, among others), to ensure that such thermal thresholds are not exceeded.

In some examples, the physical dimensions of at least the same or a different subset of the conductor elements 110 (e.g., the parallel conductor elements 110a) may be selected such that the current transmission efficiency of the subset is reduced when an operating current at a high end of the predetermined range flows therethrough, relative to when an expected average operating current flows therethrough. For example, it may be acceptable for the parallel conductor elements 110a to have lower current transmission efficiency when the operating current is at the high end of the predetermined range of operating currents, since such high current flow may be expected to be short-lived (e.g., due to transient shading conditions). In some examples, a 0.1% reduction in transmission efficiency may be considered acceptable for series conductor elements 110b. For parallel conductor elements 110a, the transmission efficiency may be limited by heating and therefore there may not be a clearly defined threshold for acceptable reduction transmission efficiency; however, trial-and-error or testing may be carried out to determine acceptable heating and/or reduction in transmission efficiency for the parallel conductor elements 110a.

In some examples, the physical dimensions of at least the same or a different subset of the conductor elements 110 (e.g., at least the parallel conductor elements 110a) may be selected to reduce or minimize interference with the optical path and also have ampacity to conduct current within a predetermined range of anticipated operating currents resulting from varying operating conditions, including shading of one or more solar cells 152 in the solar cell array 100.

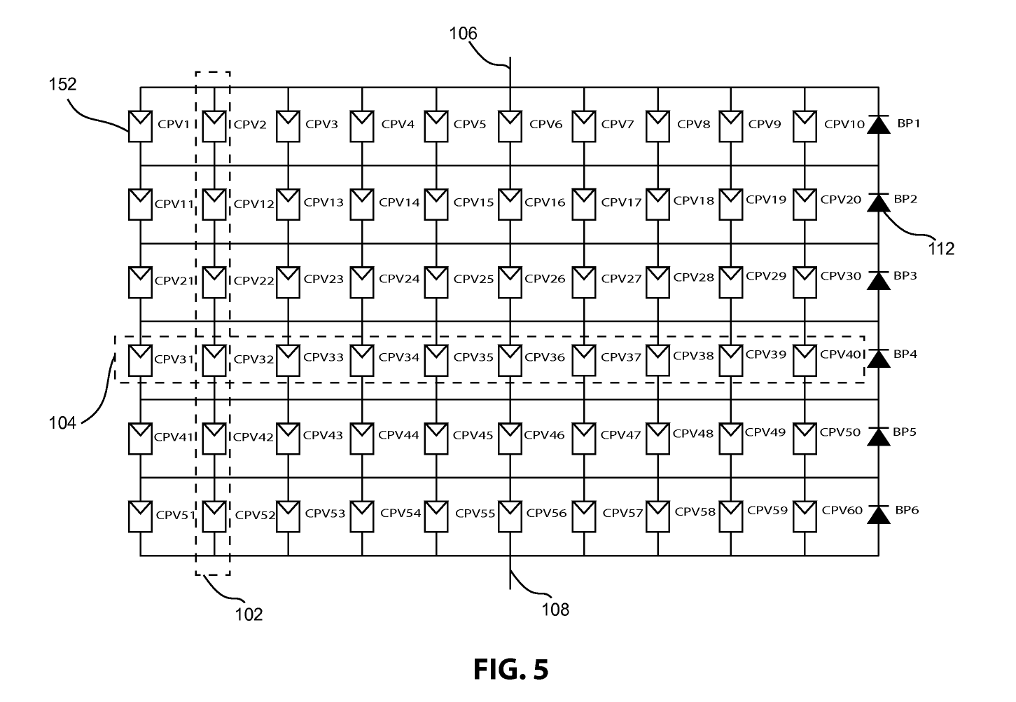

FIG. 5 shows an electrical diagram representing an example solar cell array 100 in accordance with the present disclosure in which there are six solar cells 152 connected in series in each row 102, and ten solar cells 152 connected in parallel in each column 104, as well as one bypass diode 112 connected in parallel with each column. In this diagram, the solar cells 152 are represented as solar cells (labeled CPV) and the bypass diodes 112 are represented as reverse diodes (labeled BP). As an example, the solar cell labeled CPV12 is in series connection with solar cells CPV2, CPV22, CPV32, CPV42 and CPV52 along its row 102, and is in parallel connection with solar cells CPV11 and CPV13-20 along its column 104.

As shown in FIG. 5, in some examples, the solar cell array 100 may include one or more bypass diodes 112 connected in inverse parallel with the solar cells 152 of each column 104. Each column 104 may be in parallel connection with one or more bypass diodes 112. The number of bypass diodes 112 in parallel connection with a given column 104 may be less than the number of solar cells 152 in the given column 104. That is, where the number of bypass diodes 112 connected in parallel with the given column 104 is n, then n may be governed by 1<=n< number of solar cells 152 in the given column 104.

An upper limit of the predetermined range of anticipated operating currents for the parallel conductor elements 110a may be the current generated in the parallel connections when the one or more bypass diodes 112 conduct current. This upper limit may be lower where two or more bypass diodes 112 are in parallel connection with a given column 104, compared to where a single bypass diode is in parallel connection with the given column 104.

The bypass diodes 112 may be provided as a component of the solar cell units 150 in one or more selected rows 102, while the solar cell units 150 of the remaining rows 102 are not provided with bypass diodes 112. For example, the solar cell unit 150 illustrated in FIG. 4 may be used only in one row 102 while other rows 102 do not include any bypass diodes 112, with the result that each column 104 is in parallel connection with only one bypass diode 112. In other examples, none of the solar cell units 150 may be provided with a bypass diode 112 and the bypass diodes 112 may be added as additional components to the solar cell array 100. Any suitable bypass diode 112 may be used. For example, Vishay™ SC070H045A5P or SC070H030A5P may be suitable.

As shown in FIG. 4, the solar cell unit 150 may support the solar cell 152 on a substrate 154. The solar cell 152 may be any suitable solar cell 152. For example, the solar cell 152 may be a multi-junction (e.g., triple-junction) solar cell including a plurality of diodes each associated with converting a respective received light wavelength range to electrical power. An example of a suitable triple-junction solar cell is described by Sakurada et al. (Jpn. J. Appl. Phys. 50 (2011) 04DP13), among other possible designs. A commercial solar cell that may be suitable is Spectrolab™ C3MJ The solar cell 152 may be designed to be relatively small, for example having a footprint of about 5 mm² or less. One example solar cell 152 may have a footprint of 1.3 mm×1.3 mm. A positive electrical terminal 156a and a negative electrical terminal 156b may be provided on the substrate 154, and each electrical terminal 156a, 156b may be electrically connected to the solar cell 152. For example, each solar cell 152 may include one or more wire bonds 158 to at least one of the terminals 156a, 156b. The wire bond(s) 158 may be configured to fail (e.g., physically break) if the current passing through the wire bond(s) 158 exceeds a threshold amount. The threshold current may be predetermined according to the operating limits of the solar cell 152. The wire bond(s) 158 may thus act similarly to a fuse, electrically isolating the solar cell 152 from the rest of the solar cell array 100 when the threshold current is exceeded. The terminals 156a, 156b and/or the wire bond(s) 158 may be formed from the same conductive material, such as gold. The bypass diode 112, if provided on the solar cell unit 150, may also be electrically connected to the terminals 156a, 156b by one or more wire bonds 158. In the example shown, the solar cell unit 150 may be about 7.5 mm×7.5 mm in size.

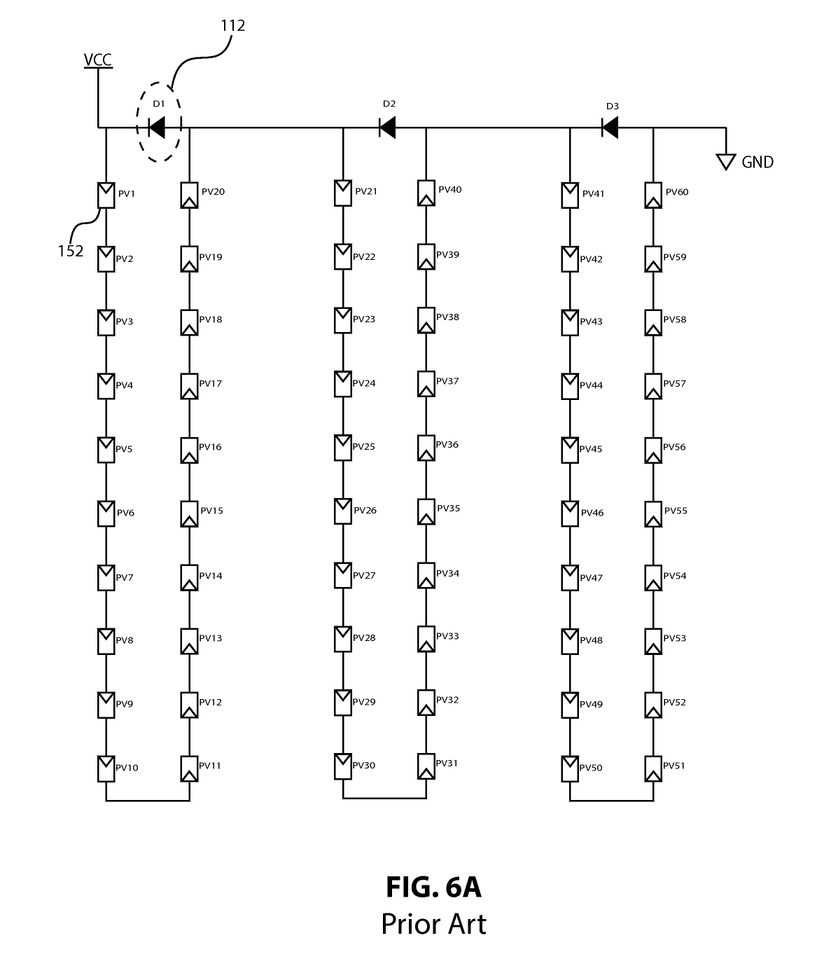

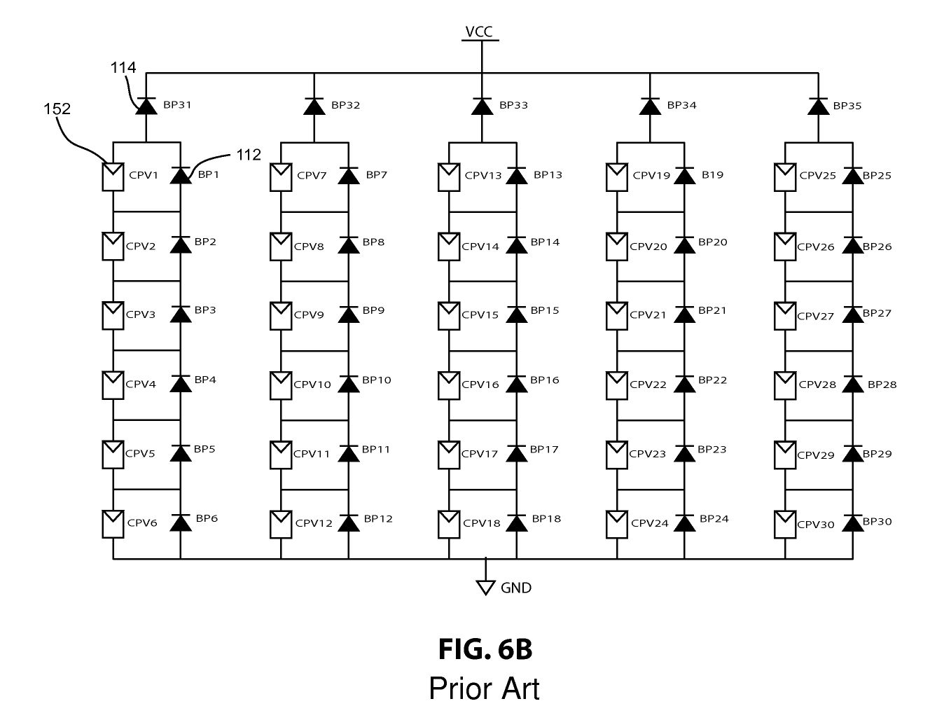

The electrical diagram of FIG. 5 may be compared with the electrical diagrams of conventional solar cell arrays, shown in FIGS. 6A and 6B. In the conventional array of FIG. 6A, the solar cells 152 are only connected in series, and there is no parallel connection between solar cells 152. Further, bypass diodes 112 are required, which may be in order to avoid reverse biasing of the solar cells 152. This arrangement typically results in a drop in the overall performance when even one solar cell 152 in the array underperforms (e.g., due to manufacturing inconsistencies or due to shading). There may also be a risk of overloading the underperforming solar cell 152. In the conventional array of FIG. 6B, the solar cells 152 are connected with each other in parallel only at either end of a row 102. Each solar cell 152 is connected in parallel with a bypass diode 112. There is no connection between each solar cell 152 of adjacent columns 104. Further, blocking diodes 114 are required at the end of each row 102, which may be in order to avoid current forward biasing an underperforming row 102. Such an arrangement requires a high number of bypass diodes 112 and blocking diodes 114, which may increase the overall size of the array as well as manufacturing costs and complexity, and may cause a reduction in efficiency.

In the disclosed solar cell array 100, solar cells 152 of each row 102 are connected in series and solar cells 152 of each column 104 are connected in parallel. This may help to reduce any adverse effects resulting from any imbalance in current among the solar cells 152. A higher number of columns 104 may provide greater mitigation of adverse effects. For example, it may be useful for the solar cell array 100 to have at least 15 solar cells 152 in each column 104. Parallel electrical connections may allow current flow to redistribute in order to bypass a lower performing solar cell 152 (e.g., a solar cell 152 that is shaded) without activating the bypass diode 112, thus avoiding limiting the overall performance of the row 102 containing the lower performing solar cell 152. Further, this arrangement may allow the number of bypass diodes 112 to be reduced. For example, a single bypass diode 112 per column 104 may be sufficient. The need for blocking diodes 114 may also be obviated.

Current may be expected to flow along the parallel electrical connections only when there are current and/or voltage imbalances among the solar cells 152. As such, in unshaded conditions, the current flowing along the conductor elements 110a providing the parallel electrical connections may be expected to be small compared to the current expected to flow along the conductor elements 110b providing the series electrical connections. The current flowing along the parallel conductor elements 110a may be expected to be significant only in shaded or partially shaded conditions, which may be only a small portion of the total operating time. Accordingly, a lower ampacity for the parallel conductor elements 110a may be acceptable from a power loss perspective. A lower ampacity for the parallel conductor elements 110a may be acceptable from a thermal perspective in some examples, such as where a multiplicity of bypass diodes is used in each column 104. In this way, the physical dimensions and/or number of the conductor elements 110a may be reduced, in order to reduce interference of the conductor elements 110 in the optical path, while still ensuring that the ampacity of the conductor elements 110 is sufficient to conduct current within the predetermined range of anticipated operating currents.

The embodiments of the present disclosure described above are intended to be examples only. The present disclosure may be embodied in other specific forms. Alterations, modifications and variations to the disclosure may be made without departing from the intended scope of the present disclosure. While the systems, devices and processes disclosed and shown herein may comprise a specific number of elements/components, the systems, devices and assemblies could be modified to include additional or fewer of such elements/components. For example, while any of the elements/components disclosed may be referenced as being singular, the embodiments disclosed herein could be modified to include a plurality of such elements/components. Selected features from one or more of the above-described embodiments may be combined to create alternative embodiments not explicitly described. All values and sub-ranges within disclosed ranges are also disclosed. The subject matter described herein intends to cover and embrace all suitable changes in technology. All references mentioned are hereby incorporated by reference in their entirety.

1. A solar cell array, comprising:
a matrix of solar cells arranged on a substrate in rows and columns; and
a plurality of conductor elements connecting the solar cells within each column in parallel and the solar cells of each row in series;
the conductor elements being arranged on the substrate in an optical path of light to the solar cells;
wherein the conductor elements are physically dimensioned to reduce interference with the optical path and have current-carrying capacity configured to conduct current within a predetermined range of anticipated operating currents.

2. The solar cell array of claim 1 wherein the physical dimensions of at least a subset of the conductor elements are selected such that heat generated thereby is substantially negligible when an average operating current flows therethrough and the heat generated thereby is elevated but lower than a predetermined heat threshold when an operating current at an upper limit of the predetermined range flows therethrough, the predetermined heat threshold being lower than a heat profile at which the solar cell array would suffer physical damage.

3. The solar cell array of claim 1 wherein the physical dimensions of at least a subset of the conductor elements are selected such that a current transmission efficiency is reduced when an operating current at a high end of the predetermined range flows therethrough relative to when an average operating current flows therethrough.

4. The solar cell array of claim 1 wherein the physical dimensions of at least a subset of the conductor elements are selected to optimally minimize interference with the optical path and also have current-carrying capacity configured to conduct current within a predetermined range of anticipated operating currents resulting from varying operating conditions including shading of portions of the matrix of solar cells.

5. The solar cell array of claim 1 wherein each column of solar cells includes a number (n) of one or more bypass diodes connected in inverse parallel with the solar cells of the column, wherein 1<=n< the number of solar cells in the column.

6. The solar cell array of claim 5 wherein an upper limit of the predetermined range of anticipated operating currents is selected to be a current generated along a given column when the one or more bypass diodes of the given column conduct current.

7. The solar cell array of claim 5 wherein there is a plurality of bypass diodes connected in each column, and wherein the conductor elements connecting the solar cells in parallel along the columns have lower ampacity than the conductor elements connecting the solar cells in series along the rows.

8. The solar cell array of claim 5 wherein there is a single bypass diode connected in each column, and wherein the conductor elements connecting the solar cells in parallel along the columns have greater ampacity than the conductor elements connecting the solar cells in series along the rows.

9. The solar cell array of claim 1 wherein the solar cells in each column are electrically connected by at least one conductor element to a respective one of the solar cells in an adjacent column.

10. The solar cell array of claim 9 wherein the elongate connectors and the conductor elements are formed from the same conductive material, wherein a minimum conductive cross-sectional area of the elongate connector between adjacent columns is less than a minimum conductive cross-sectional area of all of the conductor elements that serially connect any pair of solar cells in the adjacent columns.

11. The solar cell array of claim 1 wherein each of the solar cells is a multi-junction solar cell comprising a plurality of diodes each associated with converting a respective received light wavelength range to electrical power.

12. The solar cell array of claim 1 wherein each solar cell includes a wire bond to a terminal thereof that is configured to fail if the current passing through the wire bond exceeds a threshold amount and thereby electrically isolate the solar cell from the remaining solar cells.

13. A solar module comprising the solar cell array of claim 1, further comprising a focusing layer comprising a plurality of light concentrating optics, each light concentrating optics being optically coupled to the solar cell array to focus light on a corresponding one of the solar cells.

14. A solar module comprising the solar cell array of claim 1, further comprising a focusing layer comprising a plurality of light concentrating optics, each light concentrating optics being optically coupled to a respective reflector element of a reflector layer to focus light on the respective reflector element, each reflector element being optically coupled to the solar cell array to direct light on a corresponding one of the solar cells.

15. A solar power system comprising the solar cell array of claim 1.
